(19) United States
(12) Patent Application Publication
(10) Pub. No.: US 2017/0245379 A1
(43) Pub. Date: Aug. 24, 2017

(54) SHORT DETECTION CIRCUIT AND DISPLAY DEVICE INCLUDING THE SAME

(71) Applicant: Samsung Display Co., LTD., Yongin-si (KR)

(72) Inventor: Hyun-Suk KANG, Asan-si (KR)

(21) Appl. No.: 15/433,936

(22) Filed: Feb. 15, 2017

(30) Foreign Application Priority Data
Feb. 23, 2016 (KR) 10-2016-0020939

(51) Int. Cl. H05K 5/00; H02H 3/16; G01R 31/28; G09G 3/3225; G01R 31/02; H02H 1/00; G05F 1/46

(52) U.S. Cl. CPC H05K 5/0017; H02H 1/0007; H02H 3/16; G05F 1/46; G09G 3/3225; G01R 31/025; G01R 31/2825; H02H 7/20

(57) ABSTRACT

A short detection circuit includes a reference voltage generator that generates a reference voltage based on a power voltage, a comparison voltage generator that generates a comparison voltage that is higher or lower than a normal state voltage of a short detection target voltage by a predetermined adjustment voltage based on the reference voltage, a voltage comparator that generates a comparison result voltage by comparing the short detection target voltage with the comparison voltage, and a short detector that determines whether a target line transferring the short detection target voltage is electrically shorted based on the comparison result voltage. Thus, the short detection circuit can accurately detect an electrical short due to particles that exist in a display device.

### CROSS-REFERENCE TO RELATED APPLICATION(S)

This application claims priority under 35 USC §119 to Korean Patent Application No. 10-2016-0020939, filed on Feb. 23, 2016 in the Korean Intellectual Property Office (KIPO), the contents of which are incorporated herein in its entirety by reference.

### BACKGROUND

1. Technical Field

Example embodiments relate generally to a display device. More particularly, embodiments of the present inventive concept relate to a short detection circuit capable of detecting an electrical short due to particles that exist in a display device and a display device including the short detection circuit.

2. Description of the Related Art

Generally, a display device has a function that prevents an additional damage caused by a crack of a display panel and/or a damage of an internal circuit by monitoring the crack of the display panel and/or the damage of the internal circuit and by shutting down at least one of the display panel, a driving integrated circuit, and a power supply circuit when the crack of the display panel and/or the damage of the internal circuit are detected. To perform the function, the display device usually monitors voltages output from the power supply circuit (e.g., a DC-DC converter, etc) and/or voltages output from the driving integrated circuit. However, since an electrical short due to particles that exist in the display device generally occurs between lines transferring the same or similar voltages, a conventional short detection method cannot detect the electrical short due to the particles when a voltage change of the lines is relatively small. For example, when an initialization voltage VINT is −3.5V (volts) and a low power voltage ELVSS is between −3V and −3.5V in an organic light emitting display device, the initialization voltage VINT and the low power voltage ELVSS are not changed significantly when the electrical short due to the particles occurs between an initialization voltage line transferring the initialization voltage VINT and a low power voltage line transferring the low power voltage ELVSS. In other words, it is difficult for the conventional short detection method to detect the electrical short due to the particles, and thus the electrical short due to the particles may result in the additional damage of the display device.

### SUMMARY

Some example embodiments provide a short detection circuit that can accurately detect an electrical short due to particles that exist in a display device.

Some example embodiments provide a display device that can prevent an additional damage caused by an electrical short due to particles that exist in the display device by including the short detection circuit.

According to an aspect of example embodiments, a short detection circuit may include a reference voltage generator configured to generate a reference voltage based on a power voltage, a comparison voltage generator configured to generate a comparison voltage that is higher or lower than a normal state voltage of a short detection target voltage by a predetermined adjustment voltage based on the reference voltage, a voltage comparator configured to generate a comparison result voltage by comparing the short detection target voltage with the comparison voltage, and a short detector configured to determine whether a target line transferring the short detection target voltage is electrically shorted based on the comparison result voltage.

In example embodiments, the reference voltage generator may be implemented by a buck-boost converter, and the buck-boost converter may generate the reference voltage by stepping down or up the power voltage.

In example embodiments, the power voltage may be a panel power voltage or a logic power voltage.

In example embodiments, the comparison voltage generator may generate the comparison voltage by performing voltage-division on the reference voltage using a plurality of variable resistors.

In example embodiments, the voltage comparator may be implemented by an operational amplifier, the short detection target voltage may be input into a positive terminal of the operational amplifier, the comparison voltage may be input into a negative terminal of the operational amplifier, and the comparison result voltage may be output by an output terminal of the operational amplifier.

In example embodiments, the short detector may output a first monitoring signal indicating that the target line is not electrically shorted in response to determining that the comparison result voltage is within a predetermined voltage range. In addition, the short detector may output a second monitoring signal indicating that the target line is electrically shorted in response to determining that the comparison result voltage is outside the voltage range.

According to another aspect of example embodiments, a short detection circuit may include a comparison voltage generator configured to generate a comparison voltage that is higher or lower than a normal state voltage of a short detection target voltage by a predetermined adjustment voltage based on a power voltage, a voltage comparator configured to generate a comparison result voltage by comparing the short detection target voltage with the comparison voltage, and a short detector configured to determine whether a target line transferring the short detection target voltage is electrically shorted based on the comparison result voltage.

In example embodiments, the comparison voltage generator may generate the comparison voltage by performing voltage-division on the power voltage using a plurality of variable resistors.

In example embodiments, the voltage comparator may be implemented by an operational amplifier, the short detection target voltage may be input into a positive terminal of the operational amplifier, the comparison voltage may be input into a negative terminal of the operational amplifier, and the comparison result voltage may be output by an output terminal of the operational amplifier.

In example embodiments, the short detector may output a first monitoring signal indicating that the target line is not electrically shorted in response to determining that the comparison result voltage is within a predetermined voltage range. In addition, the short detector may output a second monitoring signal indicating that the target line is electrically shorted in response to determining that the comparison result voltage is outside the voltage range.

According to an aspect of example embodiments, a display device may include a display panel including a plurality of pixel circuits, a driving integrated circuit configured to drive the display panel, a power supply circuit configured to generate a short detection target voltage and a power voltage supplied to the display panel and the driving integrated circuit, and a short detection circuit configured to determine whether a target line transferring the short detection target voltage is electrically shorted and to shut down at least one selected from the display panel, the driving integrated circuit, and the power supply circuit when the target line is determined to be electrically shorted.

In example embodiments, the short detection circuit may include a reference voltage generator configured to generate a reference voltage based on the power voltage, a comparison voltage generator configured to generate a comparison voltage that is higher or lower than a normal state voltage of the short detection target voltage by a predetermined adjustment voltage based on the reference voltage, a voltage comparator configured to generate a comparison result voltage by comparing the short detection target voltage with the comparison voltage, and a short detector configured to determine whether the target line is electrically shorted based on the comparison result voltage.

In example embodiments, the power voltage may be a panel power voltage or a logic power voltage. In addition, the reference voltage generator may be implemented by a buck-boost converter, and the buck-boost converter may generate the reference voltage by stepping down or up the power voltage.

In example embodiments, the comparison voltage generator may generate the comparison voltage by performing voltage-division on the reference voltage using a plurality of variable resistors.

In example embodiments, the voltage comparator may be implemented by an operational amplifier, the short detection target voltage may be input into a positive terminal of the operational amplifier, the comparison voltage may be input into a negative terminal of the operational amplifier, and the comparison result voltage may be output by an output terminal of the operational amplifier.

In example embodiments, the short detector may output a first monitoring signal indicating that the target line is not electrically shorted in response to determining that the comparison result voltage is within a predetermined voltage range. In addition, the short detector may output a second monitoring signal indicating that the target line is electrically shorted in response to determining that the comparison result voltage is outside the voltage range.

In example embodiments, the short detection circuit may include a comparison voltage generator configured to generate a comparison voltage that is higher or lower than a normal state voltage of the short detection target voltage by a predetermined adjustment voltage based on the power voltage, a voltage comparator configured to generate a comparison result voltage by comparing the short detection target voltage with the comparison voltage, and a short detector configured to determine whether the target line is electrically shorted based on the comparison result voltage.

In example embodiments, the comparison voltage generator may generate the comparison voltage by performing voltage-division on the power voltage using a plurality of variable resistors.

In example embodiments, the voltage comparator may be implemented by an operational amplifier, the short detection target voltage may be input into a positive terminal of the operational amplifier, the comparison voltage may be input into a negative terminal of the operational amplifier, and the comparison result voltage may be output by an output terminal of the operational amplifier.

In example embodiments, the short detector may output a first monitoring signal indicating that the target line is not electrically shorted in response to determining that the comparison result voltage is within a predetermined voltage range. In addition, the short detector may output a second monitoring signal indicating that the target line is electrically shorted in response to determining that the comparison result voltage is outside the voltage range.

Therefore, a short detection circuit according to example embodiments may accurately detect an electrical short due to particles that exist in a display device by generating a comparison voltage that is higher or lower than a normal state voltage of a short detection target voltage by a predetermined adjustment voltage and by comparing the short detection target voltage with the comparison voltage to determine whether a target line transferring the short detection target voltage is electrically shorted.

In addition, a display device including the short detection circuit according to example embodiments may prevent an additional damage caused by the electrical short due to the particles by shutting down at least one of a display panel, a driving integrated circuit, and a power supply circuit when the electrical short due to the particles is detected.

### BRIEF DESCRIPTION OF THE DRAWINGS

Illustrative, non-limiting example embodiments will be more clearly understood from the following detailed description taken in conjunction with the accompanying drawings.

FIG. 1 is a block diagram illustrating a short detection circuit according to example embodiments.

FIG. 2 is a diagram illustrating an example of a comparison voltage generator included in the short detection circuit of FIG. 1.

FIG. 3 is a diagram illustrating an example of a voltage comparator included in the short detection circuit of FIG. 1.

FIG. 4 is a diagram illustrating an example in which the short detection circuit of FIG. 1 determines whether an electrical short due to particles occurs.

FIG. 5 is a block diagram illustrating a short detection circuit according to example embodiments.

FIG. 6 is a block diagram illustrating a display device according to example embodiments.

FIG. 7 is a flowchart illustrating a process in which the display device of FIG. 6 prevents an additional damage caused by an electrical short due to particles.

FIG. 8 is a flowchart illustrating a process in which the display device of FIG. 6 detects an electrical short due to particles.

FIG. 9 is a flowchart illustrating a process in which the display device of FIG. 6 determines whether an electrical short due to particles occurs.

FIG. 10 is a block diagram illustrating an electronic device according to example embodiments.

FIG. 11 is a diagram illustrating an example in which the electronic device of FIG. 10 is implemented as a television.

FIG. 12 is a diagram illustrating an example in which the electronic device of FIG. 10 is implemented as a smart phone.

### DETAILED DESCRIPTION OF THE EMBODIMENTS

Hereinafter, the present invention will be explained in detail with reference to the accompanying drawings.

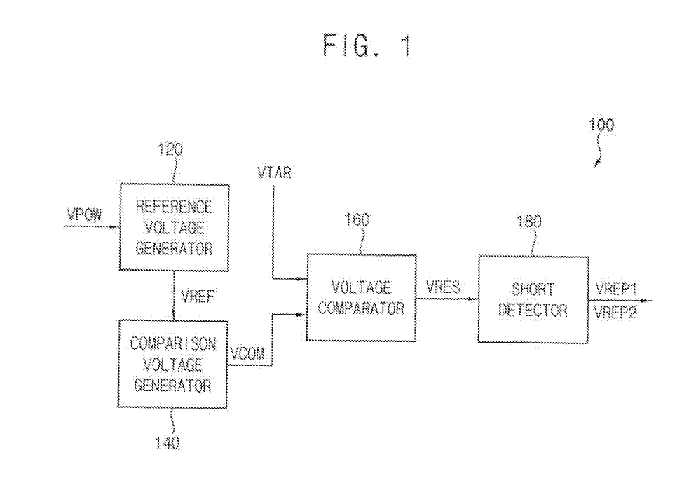

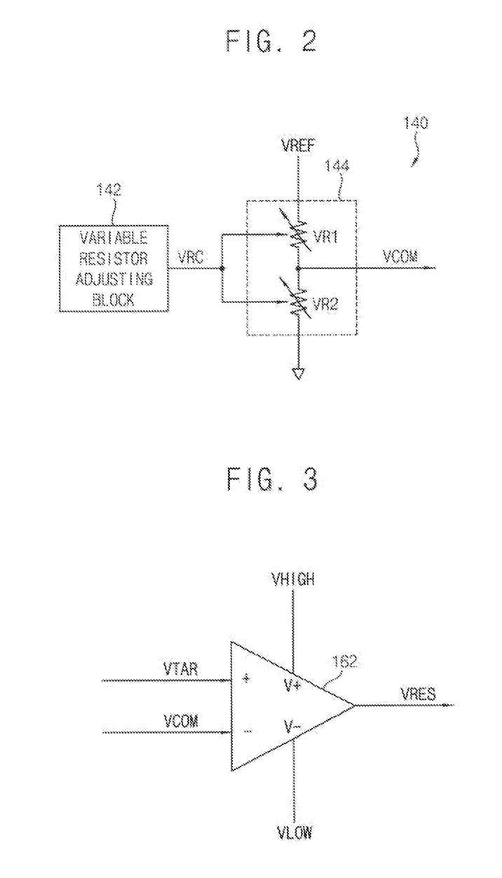

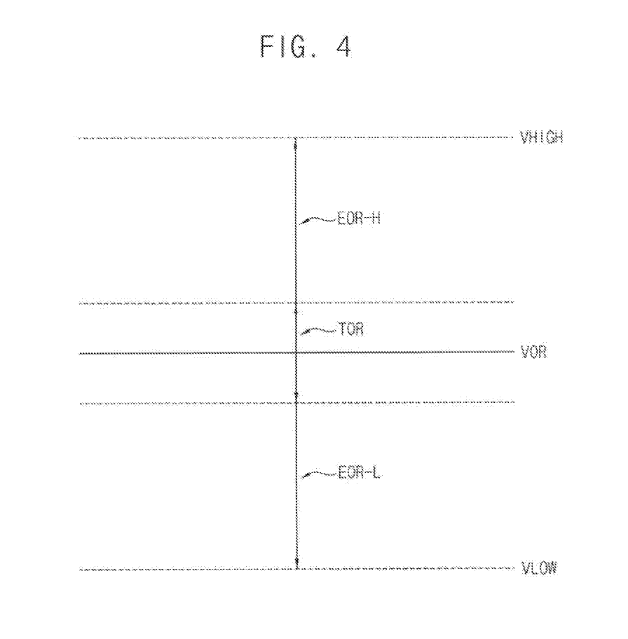

FIG. 1 is a block diagram illustrating a short detection circuit according to example embodiments. FIG. 2 is a diagram illustrating an example of a comparison voltage generator included in the short detection circuit of FIG. 1. FIG. 3 is a diagram illustrating an example of a voltage comparator included in the short detection circuit of FIG. 1. FIG. 4 is a diagram illustrating an example in which the short detection circuit of FIG. 1 determines whether an electrical short due to particles occurs.

Referring to FIGS. 1 through 4, the short detection circuit 100 may include a reference voltage generator 120, a comparison voltage generator 140, a voltage comparator 160, and a short detector 180. The short detection circuit 100 may determine whether a target line transferring a short detection target voltage VTAR is electrically shorted and may shut down at least one of a display panel, a driving integrated circuit, and a power supply circuit included in a display device when it is determined that the target line transferring the short detection target voltage VTAR is electrically shorted.

The reference voltage generator 120 may receive a power voltage VPOW, may generate a reference voltage VREF based on the power voltage VPOW, and may provide the reference voltage VREF to the comparison voltage generator 140. In some example embodiments, the power voltage VPOW may be a panel power voltage VCI that is a power voltage for driving the display panel or a logic power voltage VDDI that is a power voltage for driving logic circuits included in the driving integrated circuit. However, the power voltage VPOW is not limited thereto. In an example embodiment, the reference voltage generator 120 may be implemented by a buck-boost converter. In this case, the reference voltage generator 120 may generate the reference voltage VREF by stepping down (i.e., decreasing) or stepping up (i.e., increasing) the power voltage VPOW. In another example embodiment, when the reference voltage VREF is determined as a voltage that is higher than the power voltage VPOW, the reference voltage generator 120 may be implemented by a boost converter. In this case, the reference voltage generator 120 may generate the reference voltage VREF by stepping up the power voltage VPOW. In still another example embodiment, when the reference voltage VREF is determined as a voltage that is lower than the power voltage VPOW, the reference voltage generator 120 may be implemented by a buck converter. In this case, the reference voltage generator 120 may generate the reference voltage VREF by stepping down the power voltage VPOW.

The comparison voltage generator 140 may receive the reference voltage VREF from the reference voltage generator 120, may generate, based on the reference voltage VREF, a comparison voltage VCOM that is higher or lower than a normal state voltage of the short detection target voltage VTAR by a predetermined adjustment voltage, and may provide the comparison voltage VCOM to the voltage comparator 160. Here, the normal state voltage of the short detection target voltage VTAR indicates the short detection target voltage VTAR when the target line transferring the short detection target voltage VTAR is not electrically shorted. For example, when the adjustment voltage is set to be 0.05V, the comparison voltage VCOM may be a voltage that is higher or lower than the normal state voltage of the short detection target voltage VTAR by 0.05V. Thus, when the short detection target voltage VTAR is fluctuated (or, changed) slightly by an electrical short due to particles that exist in the display device, the short detection circuit 100 may accurately detect the electrical short due to the particles because the short detection circuit 100 detects the electrical short due to the particles by comparing the short detection target voltage VTAR with the comparison voltage VCOM. The adjustment voltage may be set to have various values according to requirements for detecting the electrical short due to the particles. In some example embodiments, the short detection target voltage VTAR may be an initialization voltage VINT for initializing pixel circuits of the display device (e.g., an organic light emitting display device, etc) or a ladder resistor reference voltage VREG1OUT for generating gray-scale voltages of the display device. However, the short detection target voltage VTAR is not limited thereto. In an example embodiment, as illustrated in FIG. 2, the comparison voltage generator 140 may include a variable resistor adjusting block 142 and a variable resistor block 144, and the variable resistor block 144 may include a plurality of variable resistors VR1 and VR2. Although it is illustrated in FIG. 2 that the variable resistor block 144 includes two variable resistors VR1 and VR2, the number of variable resistors included in the variable resistor block 144 is not limited thereto. The variable resistor adjusting block 142 may output a variable resistor adjustment signal VRC to adjust respective resistances of the variable resistors VR1 and VR2. That is, the variable resistor adjusting block 142 may control the variable resistor block 144 to output the comparison voltage VCOM that is higher or lower than the normal state voltage of the short detection target voltage VTAR by the adjustment voltage. The variable resistor block 144 may perform voltage-division on the reference voltage VREF using the variable resistors VR1 and VR2 having the respective resistances that are determined by the variable resistor adjusting block 142. As a result, the variable resistor block 144 may generate the comparison voltage VCOM that is higher or lower than the normal state voltage of the short detection target voltage VTAR by the adjustment voltage. Here, the respective resistances of the variable resistors VR1 and VR2 may be determined based on the adjustment voltage, the reference voltage VREF, and the normal state voltage of the short detection target voltage VTAR for generating the comparison voltage VCOM.

The voltage comparator 160 may receive the short detection target voltage VTAR and the comparison voltage VCOM and may generate a comparison result voltage VRES by comparing the short detection target voltage VTAR with the comparison voltage VCOM. In an example embodiment, as illustrated in FIG. 3, the voltage comparator 160 may be implemented by an operational amplifier 162. Here, the short detection target voltage VTAR may be input into a positive terminal (i.e., indicated by +) of the operational amplifier 162, the comparison voltage VCOM may be input into a negative terminal (i.e., indicated by −) of the operational amplifier 162, and the comparison result voltage VRES may be output by an output terminal of the operational amplifier 162. In this case, the comparison result voltage VRES may have a value generated by amplifying a difference between the short detection target voltage VTAR and the comparison voltage VCOM. Here, the value may be determined between a maximum driving voltage VHIGH supplied to the operational amplifier 162 (e.g., the logic power voltage VDDI) and a minimum driving voltage VLOW (e.g., a ground voltage GND). In other words, as illustrated in FIG. 4, the comparison result voltage VRES may be a voltage between the maximum driving voltage VHIGH and the minimum driving voltage VLOW. Thus, whether the target line transferring the short detection target voltage VTAR is electrically shorted may be determined according to where the comparison result voltage VRES falls among a first short range EOR-H, a non-short range TOR, and a second short range EOR-L.

The short detector 180 may receive the comparison result voltage VRES from the voltage comparator 160 and may determine whether the target line transferring the short detection target voltage VTAR is electrically shorted based on the comparison result voltage VRES. Specifically, the short detector 180 may output a first monitoring signal VREP1 indicating that the target line transferring the short detection target voltage VTAR is not electrically shorted when the comparison result voltage VRES is within a predetermined voltage range (i.e., the non-short range TOR) and may output a second monitoring signal VREP2 indicating that the target line transferring the short detection target voltage VTAR is electrically shorted when the comparison result voltage VRES is outside the predetermined voltage range. For example, the short detector 180 may use a register, a flag pin, etc to output the first monitoring signal VREP1 and the second monitoring signal VREP2. As illustrated in FIG. 4, the comparison result voltage VRES (i.e., the value generated by amplifying the difference between the short detection target voltage VTAR and the comparison voltage VCOM) may fall into one of the first short range EOR-H, the second short range EOR-L, and the non-short range TOR. Here, when the comparison result voltage VRES falls into the first short range EOR-H or the second short range EOR-L, it may be determined that the target line transferring the short detection target voltage VTAR is electrically shorted. On the other hand, when the comparison result voltage VRES falls into the non-short range TOR, it may be determined that the target line transferring the short detection target voltage VTAR is not electrically shorted.

Specifically, the non-short range TOR may be located between the first short range EOR-H and the second short range EOR-L. The short detection target voltage VTAR may not be changed when the target line transferring the short detection target voltage VTAR is not electrically shorted. In addition, the comparison voltage VCOM that is higher or lower than the normal state voltage of the short detection target voltage VTAR by the adjustment voltage may be fixed. Thus, when the target line transferring the short detection target voltage VTAR is not electrically shorted, the comparison result voltage VRES (i.e., the value generated by amplifying the difference between the short detection target voltage VTAR and the comparison voltage VCOM) may have a constant value VOR. However, since an error of the comparison result voltage VRES can be caused by various environmental factors, the comparison result voltage VRES may have an error tolerance range with respect to the constant value VOR. Thus, the error tolerance range of the comparison result voltage VRES may be set as the non-short range TOR. The first short range EOR-H may be a range that is higher than the non-short range TOR. Here, since the operational amplifier 162 cannot output a voltage that is higher than the maximum driving voltage VHIGH supplied to the operational amplifier 162, the first short range EOR-H may be located between the maximum driving voltage VHIGH and the non-short range TOR. The second short range EOR-L may be a range that is lower than the non-short range TOR. Here, since the operational amplifier 162 cannot output a voltage that is lower than the minimum driving voltage VLOW supplied to the operational amplifier 162, the second short range EOR-L may be located between the non-short range TOR and the minimum driving voltage VLOW. Thus, the short detector 180 may output the first monitoring signal VREP1 indicating that the target line transferring the short detection target voltage VTAR is not electrically shorted when the comparison result voltage VRES (i.e., the value generated by amplifying the difference between the short detection target voltage VTAR and the comparison voltage VCOM) falls into the non-short range TOR, and may output the second monitoring signal VREP2 indicating that the target line transferring the short detection target voltage VTAR is electrically shorted when the comparison result voltage VRES falls into the first short range EOR-H or the second short range EOR-L.

In some example embodiments, when the short detection target voltage VTAR only decreases below the normal state voltage of the short detection target voltage VTAR according to line arrangements as the target line transferring the short detection target voltage VTAR is electrically shorted, the operational amplifier 162 of the voltage comparator 160 may be designed to operate as a comparator, the minimum driving voltage VLOW applied to the operational amplifier 162 of the voltage comparator 160 may be set to be 0V, and the comparison voltage VCOM may be set to be lower than the normal state voltage of the short detection target voltage VTAR. In this case, the short detector 180 may determine that the target line transferring the short detection target voltage VTAR is electrically shorted when the comparison result voltage VRES output from the voltage comparator 160 is 0V. Thus, the short detector 180 may output the second monitoring signal VREP2. On the other hand, the short detector 180 may determine that the target line transferring the short detection target voltage VTAR is not electrically shorted when the comparison result voltage VRES output from the voltage comparator 160 is not 0V. Thus, the short detector 180 may output the first monitoring signal VREP1. In some example embodiments, when the short detection target voltage VTAR only increases over the normal state voltage of the short detection target voltage VTAR according to line arrangements as the target line transferring the short detection target voltage VTAR is electrically shorted, the operational amplifier 162 of the voltage comparator 160 may be designed to operate as a comparator, the maximum driving voltage VHIGH applied to the operational amplifier 162 of the voltage comparator 160 may be set to be a specific voltage, and the comparison voltage VCOM may be set to be higher than the normal state voltage of the short detection target voltage VTAR. In this case, the short detector 180 may determine that the target line transferring the short detection target voltage VTAR is electrically shorted when the comparison result voltage VRES output from the voltage comparator 160 is the specific voltage. Thus, the short detector 180 may output the second monitoring signal VREP2. On the other hand, the short detector 180 may determine that the target line transferring the short detection target voltage VTAR is not electrically shorted when the comparison result voltage VRES output from the voltage comparator 160 is not the specific voltage. Thus, the short detector 180 may output the first monitoring signal VREP1.

As described above, the short detection circuit 100 may accurately detect the electrical short due to the particles that exist in the display device by generating the comparison voltage VCOM that is higher or lower than the normal state voltage of the short detection target voltage VTAR by the adjustment voltage and by comparing the short detection target voltage VTAR with the comparison voltage VCOM to determine whether the target line transferring the short detection target voltage VTAR is electrically shorted. In addition, since the short detection circuit 100 can generate the comparison voltage VCOM without any additional design change even when the short detection target voltage VTAR is changed (e.g., from the initialization voltage VINT to the ladder resistor reference voltage VREG1OUT), the short detection circuit 100 may select one of various voltages used in the display device as the short detection target voltage VTAR to extensively detect the electrical short due to the particles. Further, the short detection circuit 100 may shut down at least one of the display panel, the driving integrated circuit, and the power supply circuit included in the display device if the short detection circuit 100 determines that the target line transferring the short detection target voltage VTAR is electrically shorted based on the first and second monitoring signals VREP1 and VREP2. As a result, the display device including the short detection circuit 100 may prevent an additional damage caused by the electrical short due to the particles. Although the first short range EOR-H, the non-short range TOR, and the second short range EOR-L are illustrated in FIG. 4, one or more of the first short range EOR-H, the non-short range TOR, and the second short range EOR-L may be omitted in some example embodiments. For example, according to lines adjacent to the target line transferring the short detection target voltage VTAR, the short detection target voltage VTAR may only decrease below the normal state voltage of the short detection target voltage VTAR or may only increase over the normal state voltage of the short detection target voltage VTAR. In this case, either the first short range EOR-H or the second short range EOR-L may be omitted. In addition, if it is unnecessary to consider the error tolerance range of the comparison result voltage VRES corresponding to the value generated by amplifying the difference between the short detection target voltage VTAR and the comparison voltage VCOM, the non-short range TOR may be omitted.

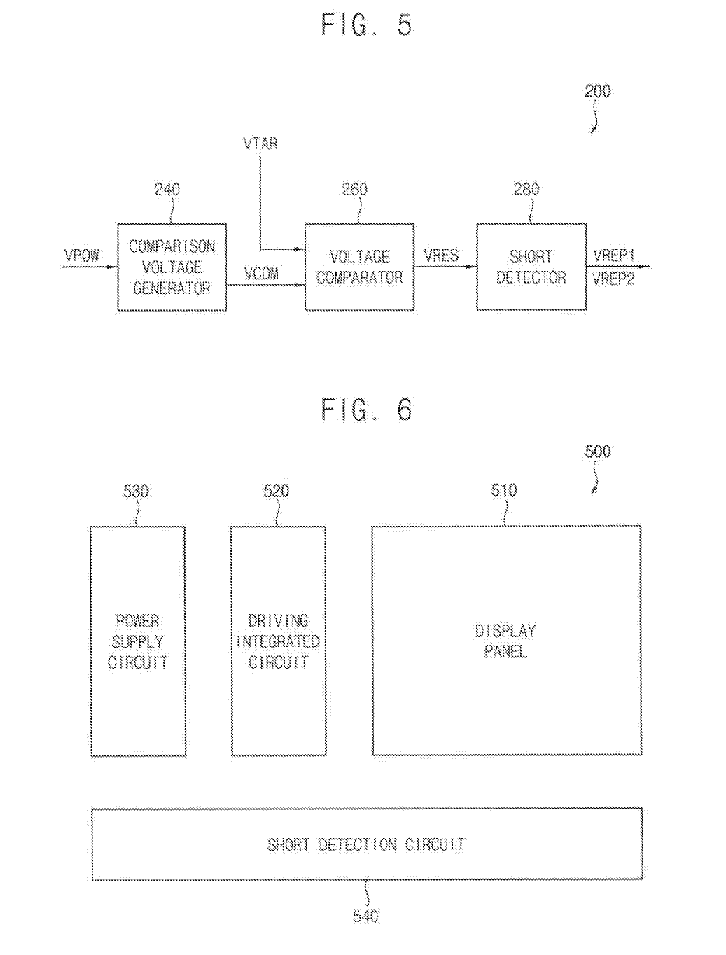

FIG. 5 is a block diagram illustrating a short detection circuit according to example embodiments.

Referring to FIG. 5, the short detection circuit 200 may include a comparison voltage generator 240, a voltage comparator 260, and a short detector 280. The short detection circuit 200 may determine whether a target line transferring a short detection target voltage VTAR is electrically shorted and may shut down at least one of a display panel, a driving integrated circuit, and a power supply circuit included in a display device if it is determined that the target line transferring the short detection target voltage VTAR is electrically shorted.

The comparison voltage generator 240 may receive a power voltage VPOW, may generate, based on the power voltage VPOW, a comparison voltage VCOM that is higher or lower than a normal state voltage of the short detection target voltage VTAR by a predetermined adjustment voltage, and may provide the comparison voltage VCOM to the voltage comparator 260. In some example embodiments, the power voltage VPOW may be a panel power voltage VCI that is a power voltage for driving the display panel or a logic power voltage VDDI that is a power voltage for driving logic circuits included in the driving integrated circuit. However, the power voltage VPOW is not limited thereto. Here, the normal state voltage of the short detection target voltage VTAR indicates the short detection target voltage VTAR when the target line transferring the short detection target voltage VTAR is not electrically shorted. For example, when the adjustment voltage is set to be 0.05V, the comparison voltage VCOM may be a voltage that is higher or lower than the normal state voltage of the short detection target voltage VTAR by 0.05V. Thus, when the short detection target voltage VTAR is fluctuated (or, changed) slightly by an electrical short due to particles that exist in the display device, the short detection circuit 200 may accurately detect the electrical short due to the particles because the short detection circuit 200 detects the electrical short due to the particles by comparing the short detection target voltage VTAR with the comparison voltage VCOM. The adjustment voltage may be set to have various values according to requirements for detecting the electrical short due to the particles. In some example embodiments, the short detection target voltage VTAR may be an initialization voltage VINT for initializing pixel circuits of the display device or a ladder resistor reference voltage VREG1OUT for generating gray-scale voltages of the display device. However, the short detection target voltage VTAR is not limited thereto. In an example embodiment, the comparison voltage generator 240 may include a variable resistor adjusting block and a variable resistor block, and the variable resistor block may include a plurality of variable resistors. The variable resistor adjusting block may output a variable resistor adjustment signal to adjust respective resistances of the variable resistors. That is, the variable resistor adjusting block may control the variable resistor block to output the comparison voltage VCOM that is higher or lower than the normal state voltage of the short detection target voltage VTAR by the adjustment voltage. The variable resistor block may perform voltage-division on the power voltage VPOW using the variable resistors having the respective resistances that are determined by the variable resistor adjusting block. As a result, the variable resistor block may generate the comparison voltage VCOM that is higher or lower than the normal state voltage of the short detection target voltage VTAR by the adjustment voltage. Here, the respective resistances of the variable resistors may be determined based on the adjustment voltage, the power voltage VPOW, and the normal state voltage of the short detection target voltage VTAR for generating the comparison voltage VCOM.

The voltage comparator 260 may receive the short detection target voltage VTAR and the comparison voltage VCOM and may generate a comparison result voltage VRES by comparing the short detection target voltage VTAR with the comparison voltage VCOM. In an example embodiment, the voltage comparator 260 may be implemented by an operational amplifier. Here, the short detection target voltage VTAR may be input into a positive terminal of the operational amplifier, the comparison voltage VCOM may be input into a negative terminal of the operational amplifier, and the comparison result voltage VRES may be output by an output terminal of the operational amplifier. In this case, the comparison result voltage VRES may have a value generated by amplifying a difference between the short detection target voltage VTAR and the comparison voltage VCOM. Here, the value may be determined between a maximum driving voltage supplied to the operational amplifier (e.g., the logic power voltage VDDI) and a minimum driving voltage (e.g., a ground voltage GND). In other words, the comparison result voltage VRES may be a voltage between the maximum driving voltage and the minimum driving voltage. Thus, whether the target line transferring the short detection target voltage VTAR is electrically shorted may be determined according to where the comparison result voltage VRES falls among a first short range, a non-short range, and a second short range.

The short detector 280 may receive the comparison result voltage VRES from the voltage comparator 260 and may determine whether the target line transferring the short detection target voltage VTAR is electrically shorted based on the comparison result voltage VRES. Specifically, the short detector 280 may output a first monitoring signal VREP1 indicating that the target line transferring the short detection target voltage VTAR is not electrically shorted when the comparison result voltage VRES is within a predetermined voltage range (i.e., the non-short range) and may output a second monitoring signal VREP2 indicating that the target line transferring the short detection target voltage VTAR is electrically shorted when the comparison result voltage VRES is outside the predetermined voltage range. For example, the short detector 280 may use a register, a flag pin, etc to output the first monitoring signal VREP1 and the second monitoring signal VREP2. As described above, the comparison result voltage VRES (i.e., the value generated by amplifying the difference between the short detection target voltage VTAR and the comparison voltage VCOM) may fall into one of the first short range, the second short range, and the non-short range. Here, when the comparison result voltage VRES falls into the first short range or the second short range, it may be determined that the target line transferring the short detection target voltage VTAR is electrically shorted. On the other hand, when the comparison result voltage VRES falls into the non-short range, it may be determined that the target line transferring the short detection target voltage VTAR is not electrically shorted.

Specifically, the non-short range may be located between the first short range and the second short range. The short detection target voltage VTAR may not be changed when the target line transferring the short detection target voltage VTAR is not electrically shorted. In addition, the comparison voltage VCOM that is higher or lower than the normal state voltage of the short detection target voltage VTAR by the adjustment voltage may be fixed. Thus, when the target line transferring the short detection target voltage VTAR is not electrically shorted, the comparison result voltage VRES (i.e., the value generated by amplifying the difference between the short detection target voltage VTAR and the comparison voltage VCOM) may have a constant value. However, since an error of the comparison result voltage VRES can be caused by various environmental factors, the comparison result voltage VRES may have an error tolerance range with respect to the constant value. Thus, the error tolerance range of the comparison result voltage VRES may be set as the non-short range. The first short range may be a range that is higher than the non-short range. Here, since the operational amplifier cannot output a voltage that is higher than the maximum driving voltage supplied to the operational amplifier, the first short range may be located between the maximum driving voltage and the non-short range. The second short range may be a range that is lower than the non-short range. Here, since the operational amplifier cannot output a voltage that is lower than the minimum driving voltage supplied to the operational amplifier, the second short range may be located between the non-short range and the minimum driving voltage. Thus, the short detector 280 may output the first monitoring signal VREP1 indicating that the target line transferring the short detection target voltage VTAR is not electrically shorted when the comparison result voltage VRES (i.e., the value generated by amplifying the difference between the short detection target voltage VTAR and the comparison voltage VCOM) falls into the non-short range, and may output the second monitoring signal VREP2 indicating that the target line transferring the short detection target voltage VTAR is electrically shorted when the comparison result voltage VRES falls into the first short range or the second short range.

In some example embodiments, when the short detection target voltage VTAR only decreases below the normal state voltage of the short detection target voltage VTAR according to line arrangements as the target line transferring the short detection target voltage VTAR is electrically shorted, the operational amplifier of the voltage comparator 260 may be designed to operate as a comparator, the minimum driving voltage applied to the operational amplifier of the voltage comparator 260 may be set to be 0V, and the comparison voltage VCOM may be set to be lower than the normal state voltage of the short detection target voltage VTAR. In this case, the short detector 280 may determine that the target line transferring the short detection target voltage VTAR is electrically shorted when the comparison result voltage VRES output from the voltage comparator 260 is 0V. Thus, the short detector 280 may output the second monitoring signal VREP2. On the other hand, the short detector 280 may determine that the target line transferring the short detection target voltage VTAR is not electrically shorted when the comparison result voltage VRES output from the voltage comparator 260 is not 0V. Thus, the short detector 280 may output the first monitoring signal VREP1. In some example embodiments, when the short detection target voltage VTAR only increases over the normal state voltage of the short detection target voltage VTAR according to line arrangements as the target line transferring the short detection target voltage VTAR is electrically shorted, the operational amplifier of the voltage comparator 260 may be designed to operate as a comparator, the maximum driving voltage applied to the operational amplifier of the voltage comparator 260 may be set to be a specific voltage, and the comparison voltage VCOM may be set to be higher than the normal state voltage of the short detection target voltage VTAR. In this case, the short detector 280 may determine that the target line transferring the short detection target voltage VTAR is electrically shorted when the comparison result voltage VRES output from the voltage comparator 260 is the specific voltage. Thus, the short detector 280 may output the second monitoring signal VREP2. On the other hand, the short detector 280 may determine that the target line transferring the short detection target voltage VTAR is not electrically shorted when the comparison result voltage VRES output from the voltage comparator 260 is not the specific voltage. Thus, the short detector 280 may output the first monitoring signal VREP1.

As described above, the short detection circuit 200 may accurately detect the electrical short due to the particles that exist in the display device by generating the comparison voltage VCOM that is higher or lower than the normal state voltage of the short detection target voltage VTAR by the adjustment voltage and by comparing the short detection target voltage VTAR with the comparison voltage VCOM to determine whether the target line transferring the short detection target voltage VTAR is electrically shorted. In addition, since the short detection circuit 200 can generate the comparison voltage VCOM without any additional design change even when the short detection target voltage VTAR is changed (e.g., from the initialization voltage VINT to the ladder resistor reference voltage VREG1OUT), the short detection circuit 200 may select one of various voltages used in the display device as the short detection target voltage VTAR to extensively detect the electrical short due to the particles. Further, the short detection circuit 200 may shut down at least one of the display panel, the driving integrated circuit, and the power supply circuit included in the display device if the short detection circuit 200 determines that the target line transferring the short detection target voltage VTAR is electrically shorted based on the first and second monitoring signals VREP1 and VREP2. As a result, the display device including the short detection circuit 200 may prevent an additional damage caused by the electrical short due to the particles. One or more of the first short range, the non-short range, and the second short range may be omitted in some example embodiments. For example, according to lines adjacent to the target line transferring the short detection target voltage VTAR, the short detection target voltage VTAR may only decrease below the normal state voltage of the short detection target voltage VTAR or may only increase over the normal state voltage of the short detection target voltage VTAR. In this case, either the first short range or the second short range may be omitted. In addition, if it is unnecessary to consider the error tolerance range of the comparison result voltage VRES corresponding to the value generated by amplifying the difference between the short detection target voltage VTAR and the comparison voltage VCOM, the non-short range may be omitted.

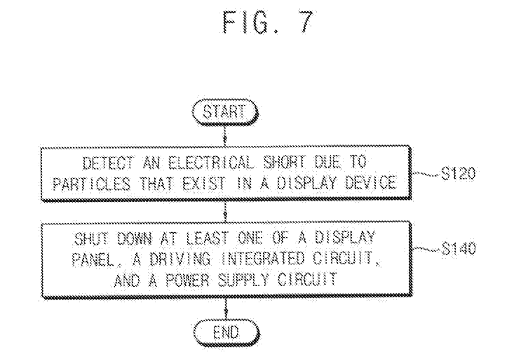

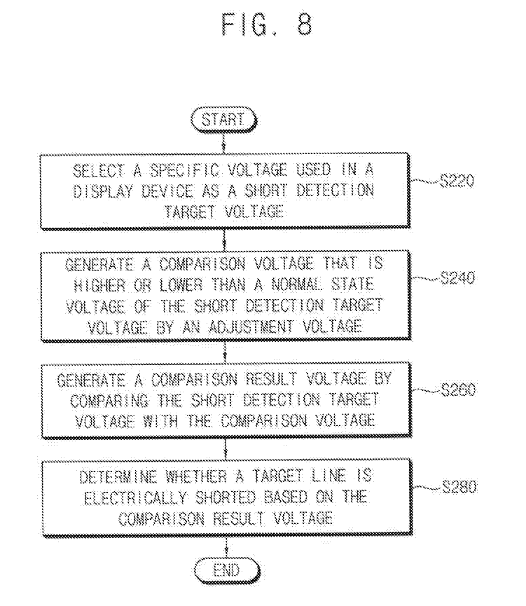

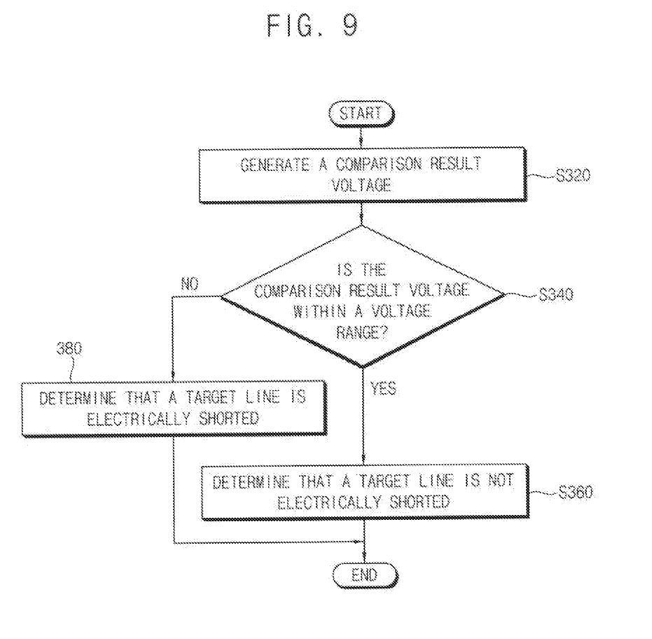

FIG. 6 is a block diagram illustrating a display device according to example embodiments. FIG. 7 is a flowchart illustrating a process in which the display device of FIG. 6 prevents an additional damage caused by an electrical short due to particles. FIG. 8 is a flowchart illustrating a process in which the display device of FIG. 6 detects an electrical short due to particles. FIG. 9 is a flowchart illustrating a process in which the display device of FIG. 6 determines whether an electrical short due to particles occurs.

Referring to FIGS. 6 through 9, the display device 500 may include a display panel 510, a driving integrated circuit 520, a power supply circuit 530, and a short detection circuit 540. For example, the display device 500 may be an organic light emitting display (OLED) device or a liquid crystal display (LCD) device. However, the display device 500 is not limited thereto.

The display panel 510 may include a plurality of pixel circuits. Here, the pixel circuits may be arranged in a matrix form in the display panel 510. The driving integrated circuit 520 may drive the display panel 510. For this operation, the display panel may be connected to the driving integrated circuit 520 via various lines. Specifically, the driving integrated circuit 520 may include a scan driver, a data driver, a timing controller, etc. In this case, the display panel 510 may be connected to the scan driver via scan-lines and may be connected to the data driver via data-lines. The scan driver may provide a scan signal to the display panel 510 via the scan-lines. The data driver may provide a data signal to the display panel 510 via the data-lines. In some example embodiments, when the display device 500 is an organic light emitting display device having an emission control function, the driving integrated circuit 520 may further include an emission control driver, and the display panel 510 may be connected to the emission control driver via emission control-lines. In this case, the emission control driver may provide an emission control signal to the display panel 510 via the emission control-lines. The timing controller may generate a plurality of control signals to control the scan driver, the data driver, the emission control driver, etc. The power supply circuit 530 may supply various voltages for operations of the display device 500. In other words, the power supply circuit 530 may generate various voltages including a short detection target voltage and a power voltage supplied to the display panel 510 and the driving integrated circuit 520. The short detection circuit 540 may determine whether a target line transferring the short detection target voltage is electrically shorted and may shut down at least one of the display panel 510, the driving integrated circuit 520, and the power supply circuit 530 if it is determined that the target line transferring the short detection target voltage is electrically shorted. That is, as illustrated in FIG. 7, when the short detection circuit 540 detects an electrical short due to particles that exist in the display device 500 (S120), the short detection circuit 540 may shut down at least one of the display panel 510, the driving integrated circuit 520, and the power supply circuit 530 (S140). Thus, the display device 500 including the short detection circuit 540 may prevent an additional damage caused by the electrical short due to the particles. Here, the short detection target voltage may be an initialization voltage VINT for initializing the pixel circuits of the display device 500 or a ladder resistor reference voltage VREG1OUT for generating gray-scale voltages of the display device 500. However, the short detection target voltage for detecting the electrical short due to the particles that exist in the display device 500 is not limited thereto.

As described above, the short detection circuit 540 may accurately detect the electrical short due to the particles that exist in the display device 500 by generating a comparison voltage that is higher or lower than a normal state voltage of the short detection target voltage by a predetermined adjustment voltage and by comparing the short detection target voltage with the comparison voltage to determine whether the target line transferring the short detection target voltage is electrically shorted. That is, as illustrated in FIG. 8, the short detection circuit 540 may select one of various voltages for operations of the display device 500 as the short detection target voltage (i.e., a voltage transferred by a line having the potential to be electrically shorted) (S220), may generate the comparison voltage that is higher or lower than the normal state voltage of the short detection target voltage by the adjustment voltage (S240), may generate the comparison result voltage by comparing the short detection target voltage with the comparison voltage (S260), and may determine whether the target line transferring the short detection target voltage is electrically shorted based on the comparison result voltage (S280). Here, as illustrated in FIG. 9, after the short detection circuit 540 generates the comparison result voltage (S320), the short detection circuit 540 may determine whether the comparison result voltage is within a predetermined voltage range (i.e., a non-short range) (S340). Here, when the comparison result voltage is within the voltage range, the short detection circuit 540 may determine that the target line transferring the short detection target voltage is not electrically shorted (S360). Thus, the short detection circuit 540 may output a first monitoring signal indicating that the target line transferring the short detection target voltage is not electrically shorted. On the other hand, when the comparison result voltage is outside the voltage range, the short detection circuit 540 may determine that the target line transferring the short detection target voltage is electrically shorted (S380). Thus, the short detection circuit 540 may output a second monitoring signal indicating that the target line transferring the short detection target voltage is electrically shorted. As the short detection circuit 540 outputs the second monitoring signal, the short detection circuit 540 may shut down at least one of the display panel 510, the driving integrated circuit 520, and the power supply circuit 530. As a result, an additional damage caused by the electrical short due to the particles that exist in the display device 500 may be prevented.

In an example embodiment, the short detection circuit 540 may include a reference voltage generator that generates the reference voltage based on the power voltage, a comparison voltage generator that generates, based on the reference voltage, the comparison voltage that is higher or lower than the normal state voltage of the short detection target voltage by the adjustment voltage, a voltage comparator that generates the comparison result voltage by comparing the short detection target voltage with the comparison voltage, and a short detector that determines whether the target line transferring the short detection target voltage is electrically shorted based on the comparison result voltage. In some example embodiments, the power voltage may be a panel power voltage VCI or a logic power voltage VDDI. However, the power voltage is not limited thereto. In an example embodiment, the reference voltage generator may be implemented by a buck-boost converter. Thus, the reference voltage generator may generate the reference voltage by stepping up or down the power voltage. In another example embodiment, when the reference voltage is only to be higher than the power voltage, the reference voltage generator may be implemented by a boost converter. Thus, the reference voltage generator may generate the reference voltage by stepping up the power voltage. In still another example embodiment, when the reference voltage is only to be lower than the power voltage, the reference voltage generator may be implemented by a buck converter. Thus, the reference voltage generator may generate the reference voltage by stepping down the power voltage. In an example embodiment, the comparison voltage generator may include a variable resistor adjusting block and a variable resistor block, and the variable resistor block may include a plurality of variable resistors. Thus, the comparison voltage generator may generate the comparison voltage by performing voltage-division on the reference voltage using the variable resistors. In an example embodiment, the voltage comparator may be implemented by an operational amplifier. Here, the short detection target voltage may be input into a positive terminal of the operational amplifier, the comparison voltage may be input into a negative terminal of the operational amplifier, and the comparison result voltage may be output by an output terminal of the operational amplifier. In an example embodiment, the short detector may output a first monitoring signal indicating that the target line transferring the short detection target voltage is not electrically shorted when the comparison result voltage is within a predetermined voltage range, and may output a second monitoring signal indicating that the target line transferring the short detection target voltage is electrically shorted when the comparison result voltage is outside the voltage range. Thus, as the short detector outputs the second monitoring signal, at least one of the display panel 510, the driving integrated circuit 520, and the power supply circuit 530 may be shut down. On the other hand, as the short detector outputs the first monitoring signal, the short detection target voltage may continue to be monitored.

In another example embodiment, the short detection circuit 540 may include a comparison voltage generator that generates, based on the power voltage, the comparison voltage that is higher or lower than the normal state voltage of the short detection target voltage by the adjustment voltage, a voltage comparator that generates the comparison result voltage by comparing the short detection target voltage with the comparison voltage, and a short detector that determines whether the target line transferring the short detection target voltage is electrically shorted based on the comparison result voltage. The short detection circuit 540 of this embodiment directly generates the comparison voltage using the power voltage supplied from the power supply circuit 530. That is, the short detection circuit 540 of this embodiment does not generate the reference voltage for generating the comparison voltage. In some example embodiments, the power voltage may be a panel power voltage VCI or a logic power voltage VDDI. However, the power voltage is not limited thereto. In an example embodiment, the comparison voltage generator may include a variable resistor adjusting block and a variable resistor block, and the variable resistor block may include a plurality of variable resistors. Thus, the comparison voltage generator may generate the comparison voltage by performing voltage-division on the power voltage using the variable resistors. In an example embodiment, the voltage comparator may be implemented by an operational amplifier. Here, the short detection target voltage may be input into a positive terminal of the operational amplifier, the comparison voltage may be input into a negative terminal of the operational amplifier, and the comparison result voltage may be output by an output terminal of the operational amplifier. In an example embodiment, the short detector may output a first monitoring signal indicating that the target line transferring the short detection target voltage is not electrically shorted when the comparison result voltage is within a predetermined voltage range, and may output a second monitoring signal indicating that the target line transferring the short detection target voltage is electrically shorted when the comparison result voltage is outside the voltage range. Thus, as the short detector outputs the second monitoring signal, at least one of the display panel 510, the driving integrated circuit 520, and the power supply circuit 530 may be shut down. On the other hand, as the short detector outputs the first monitoring signal, the short detection target voltage may continue to be monitored. In brief, the display device 500 including the short detection circuit 540 may prevent the additional damage caused by the electrical short due to the particles by shutting down at least one of the display panel 510, the driving integrated circuit 520, and the power supply circuit 530 when the electrical short due to the particles occurs.

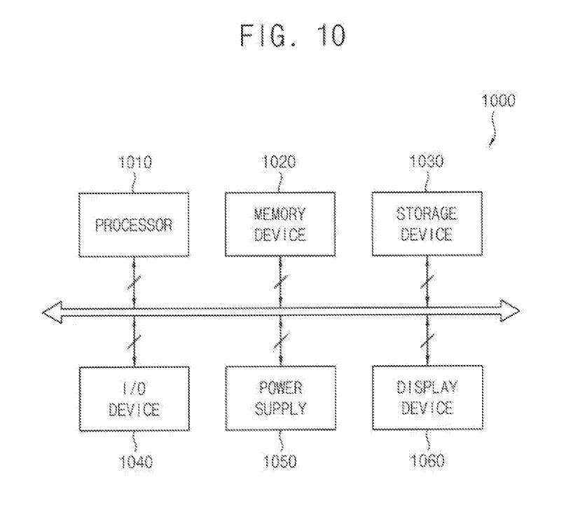

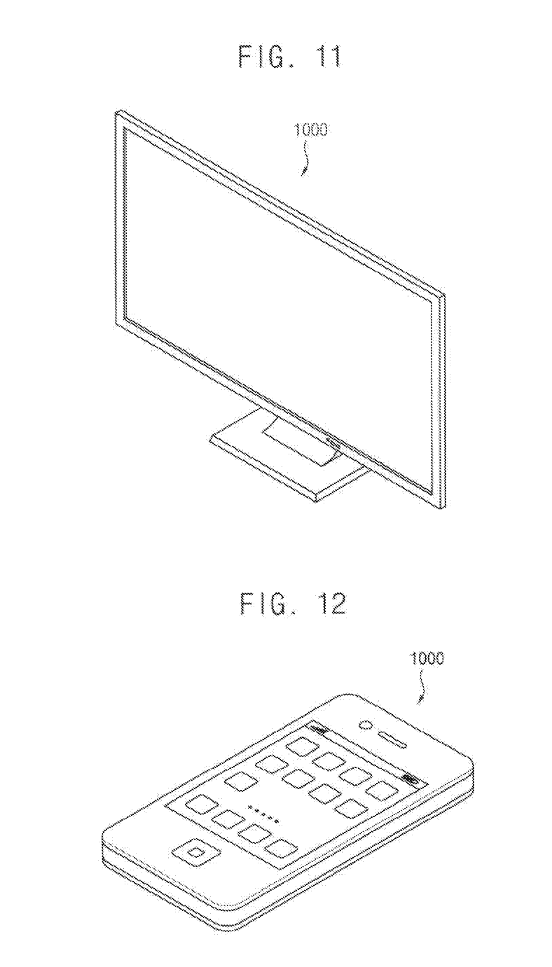

FIG. 10 is a block diagram illustrating an electronic device according to example embodiments. FIG. 11 is a diagram illustrating an example in which the electronic device of FIG. 10 is implemented as a television. FIG. 12 is a diagram illustrating an example in which the electronic device of FIG. 10 is implemented as a smart phone.

Referring to FIGS. 10 through 12, the electronic device 1000 may include a processor 1010, a memory device 1020, a storage device 1030, an input/output (I/O) device 1040, a power supply 1050, and a display device 1060. Here, the display device 1060 may correspond to the display device 500 of FIG. 6. In addition, the electronic device 1000 may further include a plurality of ports for communicating with a video card, a sound card, a memory card, a universal serial bus (USB) device, other electronic devices, etc. In an example embodiment, as illustrated in FIG. 11, the electronic device 1000 may be implemented as a television. In another example embodiment, as illustrated in FIG. 12, the electronic device 1000 may be implemented as a smart phone. However, the electronic device 1000 is not limited thereto. For example, the electronic device 1000 may be implemented as a cellular phone, a video phone, a smart pad, a smart watch, a tablet PC, a car navigation system, a computer monitor, a laptop, a head mounted display (HMD), etc.

The processor 1010 may perform various computing functions. The processor 1010 may be a micro processor, a central processing unit (CPU), an application processor (AP), etc. The processor 1010 may be coupled to other components via an address bus, a control bus, a data bus, etc. Further, the processor 1010 may be coupled to an extended bus such as a peripheral component interconnection (PCI) bus. The memory device 1020 may store data for operations of the electronic device 1000. For example, the memory device 1020 may include at least one non-volatile memory device such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, a ferroelectric random access memory (FRAM) device, etc, and/or at least one volatile memory device such as a dynamic random access memory (DRAM) device, a static random access memory (SRAM) device, a mobile DRAM device, etc. The storage device 1030 may include a solid state drive (SSD) device, a hard disk drive (HDD) device, a CD-ROM device, etc. The I/O device 1040 may include an input device such as a keyboard, a keypad, a mouse device, a touchpad, a touch-screen, etc and an output device such as a printer, a speaker, etc. The power supply 1050 may provide power for operations of the electronic device 1000.

The display device 1060 may be coupled to other components via the buses or other communication links. In some example embodiments, the display device 1060 may be included in the I/O device 1040. As described above, the display device 1060 may prevent an additional damage caused by an electrical short due to particles that exist in the display device 1060 by shutting down at least one of a display panel, a driving integrated circuit, and a power supply circuit included in the display device 1060 when the electrical short due to the particles occurs. To this end, the display device 1060 may include the display panel that includes a plurality of pixel circuits, the driving integrated circuit that drives the display panel, the power supply circuit that generates a short detection target voltage and a power voltage supplied to the display panel and the driving integrated circuit, and a short detection circuit that determines whether a target line transferring the short detection target voltage is electrically shorted and shuts down at least one of the display panel, the driving integrated circuit, and the power supply circuit if it is determined that the target line transferring the short detection target voltage is electrically shorted. Here, the short detection circuit may accurately detect the electrical short due to the particles by generating a comparison voltage that is higher or lower than a normal state voltage of the short detection target voltage by a predetermined adjustment voltage and by comparing the short detection target voltage with the comparison voltage to determine whether the target line transferring the short detection target voltage is electrically shorted. In an example embodiment, the short detection circuit may include a reference voltage generator that generates a reference voltage based on the power voltage, a comparison voltage generator that generates, based on the reference voltage, the comparison voltage that is higher or lower than the normal state voltage of the short detection target voltage by the adjustment voltage, a voltage comparator that generates a comparison result voltage by comparing the short detection target voltage with the comparison voltage, and a short detector that determines whether the target line transferring the short detection target voltage is electrically shorted based on the comparison result voltage. In another example embodiment, the short detection circuit may include a comparison voltage generator that generates, based on the power voltage, the comparison voltage that is higher or lower than the normal state voltage of the short detection target voltage by the adjustment voltage, a voltage comparator that generates a comparison result voltage by comparing the short detection target voltage with the comparison voltage, and a short detector that determines whether the target line transferring the short detection target voltage is electrically shorted based on the comparison result voltage. Since these are described above, duplicated description will not be repeated.

The present inventive concept may be applied to a display device and an electronic device including the display device. For example, the present inventive concept may be applied to a cellular phone, a smart phone, a video phone, a smart pad, a smart watch, a tablet PC, a car navigation system, a television, a computer monitor, a laptop, a head mounted display, etc.

The foregoing is illustrative of example embodiments and is not to be construed as limiting thereof. Although a few example embodiments have been described, those skilled in the art would readily appreciate that many modifications are possible in the example embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A short detection circuit comprising:
a reference voltage generator configured to generate a reference voltage based on a power voltage;
a comparison voltage generator configured to generate a comparison voltage that is higher or lower than a normal state voltage of a short detection target voltage by a predetermined adjustment voltage based on the reference voltage;
a voltage comparator configured to generate a comparison result voltage by comparing the short detection target voltage with the comparison voltage; and
a short detector configured to determine whether a target line transferring the short detection target voltage is electrically shorted based on the comparison result voltage.

2. The circuit of claim 1, wherein the reference voltage generator is implemented by a buck-boost converter, and the buck-boost converter generates the reference voltage by stepping down or up the power voltage.

3. The circuit of claim 2, wherein the power voltage is a panel power voltage or a logic power voltage.

4. The circuit of claim 1, wherein the comparison voltage generator generates the comparison voltage by performing voltage-division on the reference voltage using a plurality of variable resistors.

5. The circuit of claim 1, wherein the voltage comparator is implemented by an operational amplifier, the short detection target voltage is input into a positive terminal of the operational amplifier, the comparison voltage is input into a negative terminal of the operational amplifier, and the comparison result voltage is output by an output terminal of the operational amplifier.

6. The circuit of claim 1, wherein the short detector outputs a first monitoring signal indicating that the target line is not electrically shorted in response to determining that the comparison result voltage is within a predetermined voltage range, and
wherein the short detector outputs a second monitoring signal indicating that the target line is electrically shorted in response to determining that the comparison result voltage is outside the voltage range.

7. A short detection circuit comprising:
a comparison voltage generator configured to generate a comparison voltage that is higher or lower than a normal state voltage of a short detection target voltage by a predetermined adjustment voltage based on a power voltage;
a voltage comparator configured to generate a comparison result voltage by comparing the short detection target voltage with the comparison voltage; and
a short detector configured to determine whether a target line transferring the short detection target voltage is electrically shorted based on the comparison result voltage.

8. The circuit of claim 7, wherein the comparison voltage generator generates the comparison voltage by performing voltage-division on the power voltage using a plurality of variable resistors.

9. The circuit of claim 7, wherein the voltage comparator is implemented by an operational amplifier, the short detection target voltage is input into a positive terminal of the operational amplifier, the comparison voltage is input into a negative terminal of the operational amplifier, and the comparison result voltage is output by an output terminal of the operational amplifier.

10. The circuit of claim 7, wherein the short detector outputs a first monitoring signal indicating that the target line is not electrically shorted in response to determining that the comparison result voltage is within a predetermined voltage range, and
wherein the short detector outputs a second monitoring signal indicating that the target line is electrically shorted in response to determining that the comparison result voltage is outside the voltage range.

11. A display device comprising:
a display panel including a plurality of pixel circuits;
a driving integrated circuit configured to drive the display panel;
a power supply circuit configured to generate a short detection target voltage and a power voltage supplied to the display panel and the driving integrated circuit; and
a short detection circuit configured to determine whether a target line transferring the short detection target voltage is electrically shorted and to shut down at least one selected from the display panel, the driving integrated circuit, and the power supply circuit in response to determining that the target line is electrically shorted.

12. The device of claim 11, wherein the short detection circuit includes:
a reference voltage generator configured to generate a reference voltage based on the power voltage;
a comparison voltage generator configured to generate a comparison voltage that is higher or lower than a normal state voltage of the short detection target voltage by a predetermined adjustment voltage based on the reference voltage;
a voltage comparator configured to generate a comparison result voltage by comparing the short detection target voltage with the comparison voltage; and
a short detector configured to determine whether the target line is electrically shorted based on the comparison result voltage.

13. The device of claim 12, wherein the power voltage is a panel power voltage or a logic power voltage, and
wherein the reference voltage generator is implemented by a buck-boost converter, and the buck-boost converter generates the reference voltage by stepping down or up the power voltage.

14. The device of claim 12, wherein the comparison voltage generator generates the comparison voltage by performing voltage-division on the reference voltage using a plurality of variable resistors.

15. The device of claim 12, wherein the voltage comparator is implemented by an operational amplifier, the short detection target voltage is input into a positive terminal of the operational amplifier, the comparison voltage is input into a negative terminal of the operational amplifier, and the comparison result voltage is output by an output terminal of the operational amplifier.

16. The device of claim 12, wherein the short detector outputs a first monitoring signal indicating that the target line is not electrically shorted in response to determining that the comparison result voltage is within a predetermined voltage range, and
wherein the short detector outputs a second monitoring signal indicating that the target line is electrically shorted in response to determining that the comparison result voltage is outside the voltage range.

17. The device of claim 11, wherein the short detection circuit includes:
a comparison voltage generator configured to generate a comparison voltage that is higher or lower than a normal state voltage of the short detection target voltage by a predetermined adjustment voltage based on the power voltage;
a voltage comparator configured to generate a comparison result voltage by comparing the short detection target voltage with the comparison voltage; and
a short detector configured to determine whether the target line is electrically shorted based on the comparison result voltage.

18. The device of claim 17, wherein the comparison voltage generator generates the comparison voltage by performing voltage-division on the power voltage using a plurality of variable resistors.

19. The device of claim 17, wherein the voltage comparator is implemented by an operational amplifier, the short detection target voltage is input into a positive terminal of the operational amplifier, the comparison voltage is input into a negative terminal of the operational amplifier, and the comparison result voltage is output by an output terminal of the operational amplifier.

20. The device of claim 17, wherein the short detector outputs a first monitoring signal indicating that the target line is not electrically shorted in response to determining that the comparison result voltage is within a predetermined voltage range, and
wherein the short detector outputs a second monitoring signal indicating that the target line is electrically shorted in response to determining that the comparison result voltage is outside the voltage range.
